(19) United States
(12) Patent Application Publication
(10) Pub. No.: US 2014/0144485 A1
(43) Pub. Date: May 29, 2014

(54) IMPROVING THE LONGEVITY AND ERGONOMICS OF HYBRID SOLAR MODULES

(71) Applicants: Jérõme Mouterde, Marseille (FR); Laetitia Brottier, Malakoff (FR)

(72) Inventors: Jérõme Mouterde, Marseille (FR); Laetitia Brottier, Malakoff (FR)

(73) Assignee: SOLAIRE 2G, ROUSSET (FR)

(21) Appl. No.: 14/131,751

(22) PCT Filed: Jul. 12, 2012
(86) PCT No.: PCT/EP2012/063734

§ 371 Date: Jan. 9, 2014

(30) Foreign Application Priority Data
Jul. 19, 2011 (FR) 1156550

(51) Int. Cl. H01L 31/0525

(52) U.S. Cl. CPC H01L 31/058
USPC 136/248; 438/64

(57) ABSTRACT

At best, photovoltaic solar modules only convert 20% of solar energy into electrical energy, the rest of this energy being dissipated. This heat stored in the photovoltaic module reduces efficiency, which decreases in an inversely proportional manner to the temperature of the photovoltaic module. To dissipate and recover this heat, it is common to associate the photovoltaic module with a heat exchanger which, in addition to cooling the photovoltaic module, will supply heat, for example to heat the sanitary water of a building. This assembly forms a hybrid solar module, whose main limitation is its weight and relatively short service life. The invention described in the present document solves these two problems by replacing the first layer of the hybrid solar module, which is conventionally a glass sheet, with a material which is lighter, less rigid, more transparent, and more compatible with the material from which is constructed the heat exchanger, which now provides the system with its rigidity. A method for manufacturing these hybrid solar modules is also described.

### TECHNICAL FIELD OF THE INVENTION

The present invention relates to the field of hybrid solar systems. The invention relates more particularly to a method enabling the improvement of the service life and the output of the system. The invention likewise relates to the method of assembling photovoltaic modules to form heat exchangers, a cooling liquid circulating in said heat exchangers.

### TECHNOLOGICAL BACKGROUND OF THE INVENTION

In a manner which is known per se, a hybrid solar system consists of a photovoltaic solar module associated with a thermal part, likewise known as an exchanger or absorber, charged with cooling the photovoltaic solar module. In fact, such a module, composed of a plurality of electrically connected photovoltaic solar elements, supplies electricity by conversion of the solar energy within said photovoltaic cells. However, the rate of conversion hardly exceeds 20%, the rest of the solar energy received by the system being dissipated. The efficiency of the photovoltaic cells decreases with the temperature, of the order of 0.4% of yield per additional degree for the technology of crystalline silicon semiconductors. It is therefore crucial to control the temperature of the photovoltaic panels in order to ensure a constant, or even improved, output. In order to evacuate the heat, it is common to associate the photovoltaic module with a heat exchanger including a cooling system with circulation of air or liquid, also making it possible to use this heat for example to heat the domestic water of a building.

Conventionally, a photovoltaic solar module consists of a plurality of photovoltaic elements encapsulated in a binder, generally thermoplastic polymers. The binder is activated during a process of assembling cells by heating and pressure known as lamination. A rigid base made of transparent material, generally glass, is integrated into the panel during the lamination process on the face oriented towards the sun, and acts as a rigid support for the photovoltaic module. This layer of transparent material is commonly known as a frontsheet. On the face opposite of the module is integrated a layer of electrically insulating and impermeable material, generally a polyvinyl fluorine film, said layer being commonly known as a backsheet.

In order to produce a hybrid solar module, the photovoltaic module is assembled with a heat exchanger, by glueing this latter on the opposite face of the photovoltaic module with the aid of a special resin. This heat exchanger serves for cooling of the photovoltaic module by air or by water, and uses the calories recovered for other applications, for example the heating of the water for a building. Thus, a hybrid solar module supplies electrical energy and heat energy.

There are several limitations inherent in the technology, the main one being the material incompatibilities generating cycles of differential expansion of the hybrid solar module, causing accelerated ageing of the resin joining the photovoltaic module to the heat exchanger. Another limitation resides in the substantial weight of the hybrid solar module, which induces an increase in installation costs and limits the development of this market to buildings provided with recent and/or sufficiently resistant roofs.

A process is known in the prior art which makes it possible to manage the material incompatibilities and is described in the document U.S. 2011/0114155 A1. It is proposed to cut the metal exchanger into sub-parts. The sub-parts are spaced apart by a distance corresponding to 1% of their width, and are connected to one another with the aid of an elastic binder. This configuration has the advantage of limiting the differential expansions and increasing the service life of the panel. However, the problem of the weight of the hybrid module is not solved and there is a risk of the production costs being increased.

Likewise a process is known in the prior art for increasing the service life of the hybrid module in spite of the cycles of differential expansion of the materials. The document EP 1 873 843 discloses the possibility of applying a binder between the photovoltaic module and the heat exchanger, the binder being designed in order to better withstand the constraints associated with the expansion of the materials. In spite of everything, such a process risks generating additional costs and in no way makes it possible to decrease the weight of the installation.

Moreover, a hybrid solar panel is likewise known in the prior art of which the exchanger ensures, in addition to its initial function of cooling of the photovoltaic elements, the function of rigidity of the system. The patent WO2007/144113 discloses an exchanger which ensures the rigidity of the system, since it forms an integral part of the framework enclosing the system. However, such an exchanger remains particularly heavy, and is not adapted to all types of roofs.

### GENERAL DESCRIPTION OF THE INVENTION

Therefore the object of the present invention is to remedy one or more of the drawbacks of the prior art, by proposing a hybrid solar module installation which eliminates the problems of differential expansion, and reduces the weight.

To this end, the invention relates to a hybrid solar module, comprising at least one photovoltaic module consisting of at least one semiconductor element converting part of the solar energy into electrical energy, one of the two faces of said module being exposed to the radiation, at least one heat exchanger placed facing the face of the photovoltaic module opposed to the face exposed to the radiation, in which a cooling fluid circulates which makes it possible recover the heat energy accumulated or dissipated, characterised in that it includes:
i. a layer of transparent material suitable to be subjected to mechanical deformations compatible with the deformations undergone by the materials constituting the heat exchanger and deposited on the face of the photovoltaic module receiving the radiation, said layer being connected to the photovoltaic module by a layer of encapsulating material;
ii. a layer of encapsulating material deposited on the face of the photovoltaic module opposite the face receiving the radiation in order to fix the heat exchanger on this opposing face of the photovoltaic module;
iii. a heat exchanger of which at least the face in contact with the photovoltaic solar module is rigid and planar.

Thus, the hybrid solar module described exhibits the advantage of eliminating the differential expansions responsible for the accelerated ageing of the adhesives joining the different elements of said module. The material for replacement of the conventional glass sheet is less rigid than glass, but more transparent than this latter, at the same time increasing the conversion efficiency of the solar energy into electrical energy. On the other hand, the rigidity and the flatness of the module is transferred at least to a part of the heat exchanger. According to another feature, the hybrid solar module is compatible with the photovoltaic technologies based on semiconductors or existing organic technologies.

Thus it is possible to use photovoltaic modules resulting from technologies of different generations, and photovoltaic modules nowadays can consist of:
solar cells based on crystalline silicon semiconductors,
semiconductor thin layers,
organic solar cells.

According to another feature, the layer of transparent material covering the face of the module which is exposed to the radiation is based on fluoropolymer, said layer of material being compatible with the lamination process.

Thus there is no need to modify the production lines for photovoltaic solar panels in order to manufacture the invention.

According to another feature, the light transmission of the material layer covering the face of the photovoltaic module subjected to the radiation is greater than the light transmission of glass.

Thus the conversion efficiency of the solar energy into electrical energy is improved relative to the hybrid solar panels described in the prior art.

According to another feature, the heat exchanger is metal or made of composite material.

Thus, in addition to ensuring the rigidity of the hybrid solar module, the good thermal conductivity of the materials used makes it possible to ensure efficient cooling of the photovoltaic module.

According to another feature, the cooling of the photovoltaic module is ensured by the circulation of a liquid film in the heat exchanger.

Thus this solution offers the advantage of increasing the contact surface between the cooling liquid and the heat exchanger, which makes it possible likewise to reduce the flow of liquid circulating in the heat exchanger.

According to another feature, the heat exchanger consists of a first flat sub-part in contact with the photovoltaic module, and a second sub-part co-operating with the first in order to form the circulation channels for the cooling fluid.

Thus the choice of the shape of the second sub-part of the heat exchanger only depends upon the technical or geometric constraints associated with the cooling circuit of which this second sub-part forms a part.

According to the prior art, there is an electrically insulating material layer of which the thinness limits its thermal resistance between the photovoltaic module and the heat exchanger.

This layer is described in the prior art as being generally a polyvinyl fluorine film which has the property of being impermeable and of being an electrical insulation.

The hybrid solar module of the invention offers the possibility of eliminating this insulating and impermeable layer by shifting the sealing function or even the electrical insulation function to the heat exchanger.

According to another feature the composition of the encapsulation joining the photovoltaic module to the heat exchanger is modified in order also to make it an electrical insulation.

An additional objective of the invention is to propose a method for manufacturing a hybrid solar module.

To this end, the invention relates to a method for manufacturing a hybrid solar module, comprising at least one photovoltaic module consisting of at least one semiconductor element converting part of the solar energy into electrical energy, one of the two faces of said module being subjected to the solar radiation, at least one heat exchanger placed facing the face of the photovoltaic module opposed to the face exposed to the radiation, in which a cooling fluid circulates which makes it possible recover the heat energy accumulated or dissipated, characterised in that the method comprises the following steps:
i a step of depositing a layer of encapsulation on the face of a part of the heat exchanger facing the face of the photovoltaic module opposite the face which is subjected to the radiation;
ii a step of positioning photovoltaic elements on the layer of encapsulation;
iii a step of depositing a layer of encapsulation on the face of the photovoltaic module which is subjected to the radiation;
iv a step of positioning a transparent material layer facing the face of the photovoltaic module which is subjected to the radiation;
v a step of lamination of the hybrid solar module.

According to another feature, the steps can be carried out in reverse order, first of all the step iv, then iii, then ii then i, followed by the step v of lamination of the hybrid solar module.

According to another feature, before the positioning of the photovoltaic elements in the step i a layer of insulating material is inserted followed by the deposition of a layer of encapsulation facing the face of the photovoltaic module opposite the face which is subjected to the radiation.

According to another feature, the method is characterised in that the encapsulation of the photovoltaic module and the assembly of said module with the heat exchanger may be carried out during the same step of lamination.

According to another feature, a second sub-part of the heat exchanger is assembled with the part assembled to the photovoltaic module, following the operation of lamination enabling assembly of the hybrid solar module.

Thus the photovoltaic module can be assembled according to a method of lamination described in the prior art. The replacement of the glass sheet by a material layer less rigid and transparent makes it possible to assemble at least all or part of the heat exchanger and the photovoltaic module according to the method of lamination by reversing the order of the layers. In fact, it is easier to start the operation of lamination by the layer containing a part of the heat exchanger within the scope of the invention. It is likewise possible to constitute the assembly of the hybrid solar module in one single operation of lamination, thus avoiding the additional assembly costs. Finally, it is possible to assemble the first sub-part of the exchanger to the photovoltaic module in the course of the lamination operation, then to assemble the second sub-part of the heat exchanger by any means known to the person skilled in the art, for example by glueing.

The invention, its characteristics and advantages will be more clearly apparent from a reading of the description given with reference to the appended drawings, in which:

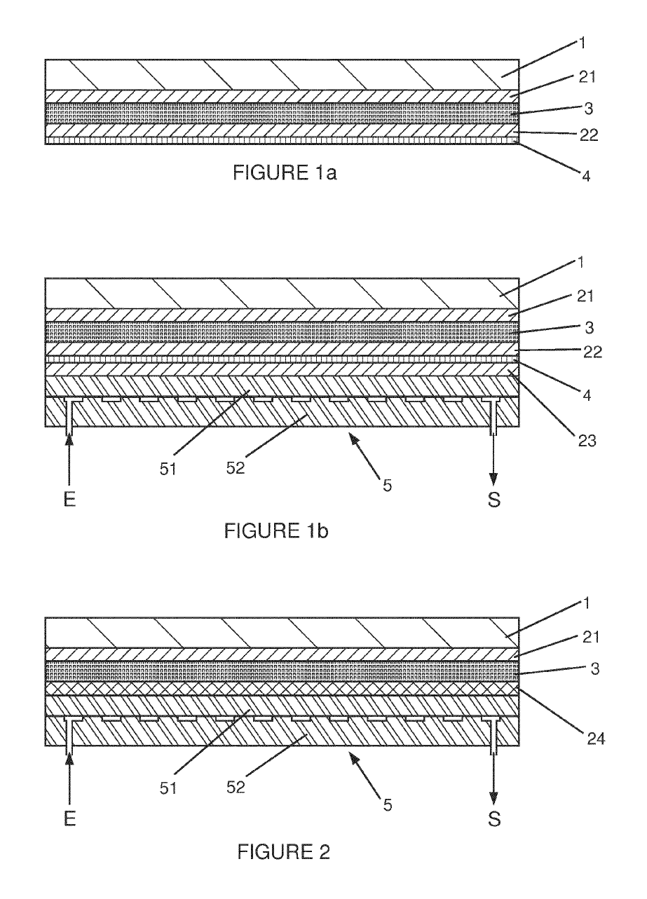

FIG. 1a shows a sectional view of the photovoltaic solar module covered by the layer transparent material;

FIG. 1b shows a sectional view of the hybrid solar module according to a first embodiment;

FIG. 2 shows a perspective view of a second embodiment of the invention.

### DESCRIPTION OF PREFERRED EMBODIMENTS OF THE INVENTION

The solar panel according to the invention is a hybrid solar module capable of producing electrical energy and heat energy from solar energy. It is intended to be used alone or in combination with other similar modules within an installation, in order that the energy produced by said panels should be exploitable, for example and in a non-limiting manner for a dwelling. Conventionally, the hybrid solar module may be defined as being an assembly of a photovoltaic solar module and a heat exchanger (5).

With reference to FIG. 1a, the hybrid solar module converts a part of the solar energy received into electrical energy by virtue of a photovoltaic module. Said photovoltaic module is composed of a plurality of photovoltaic elements (3), typically crystalline silicon semiconductors, semiconductor thin layers, or any other technology capable of achieving the photoelectric effect. These photovoltaic elements (3) are connected electrically, in series or in parallel, and are encapsulated, for example and in a non-limiting manner, in a thermoplastic polymer, for example of ethylene vinyl acetate (EVA), conventionally in the course of a lamination process, that is to say an assembly of the photovoltaic module by heating and pressure. During this step of lamination, a film (1) of material known as a “frontsheet” is deposited on the face of the photovoltaic module exposed to the radiation, said film (1) being transparent, flexible, resistant to UV, based on fluoropolymer, for example and in a non-limiting manner, ethylene tetrafluoroethylene or ETFE. This material offers a better coefficient of transmission than glass, at the same time improving the output of the installation. The film (1) is likewise much lighter than glass, significantly reducing the weight of the invention. The principal advantage of this film (1) is its relative flexibility in relation to glass. In response to the variations of temperature, the heat exchanger (5) produces cycles of expansion and of retraction, due to the nature of materials of which it is composed. Very slight in a material such as glass, these mechanical movements are likewise to be found in the film (1) deposited on the surface of the hybrid solar module. These mechanical characteristics of the film (1) make it possible to eliminate the cycles of differential expansion observed in the systems according to the prior art and which would give rise to premature ageing of adhesives, for example epoxy adhesives, enabling the assembly of the photovoltaic module and of the heat exchanger (5).

At least 80% of the solar energy received by the hybrid solar module will be dissipated in the panel. The presence of a heat exchanger (5) which is placed in front of the face of the photovoltaic module opposite the face which is exposed to the radiation makes it possible to recover the heat accumulated or dissipated in the photovoltaic module.

In one embodiment, the heat exchanger (5) and the photovoltaic module are assembled by means of an encapsulation (23), for example and in a non-limiting manner a thermoplastic polymer, for example ethylene vinyl acetate, at the end of a lamination process. Thus the cooling of the hybrid module solar is associated with the production of exploitable heat energy. The heat exchanger is produced from metal or composite material, for example and in a non-limiting manner aluminium, copper or any other metal or material is a good thermal conductor and is sufficiently rigid to ensure the cohesion of the hybrid solar module. On the other hand, in order to ensure the flatness of the hybrid solar module, the face of the heat exchanger (5) which is fixed with the aid of the encapsulation (23, 24) against the face of the photovoltaic module opposite the face which is exposed to the radiation must be flat. The cooling of the photovoltaic module is ensured by a cooling fluid, for example air or glycolated water, which is routed by ventilation and/or pumping means and circulates in the heat exchanger (5), always in the same direction, from the inlet (E) towards the outlet (S) of said heat exchanger (5). In one embodiment, the fluid circulating in the heat exchanger (5) can for example form a film moved by hydrodynamic turbulence, thus ensuring a large contact surface in the region of the face of the photovoltaic module opposite the face exposed to the radiation.

In one embodiment, the heat exchanger (5) is divided into two sub-parts (51, 52). The first sub-part (51) is flat, and is assembled against the face of the photovoltaic module opposite the face subjected to the radiation. The second sub-part (52) is free-form, and forms with the first sub-part (51) the channels for circulation of the cooling fluid. The two sub-parts (51, 52) of the heat exchanger (5) can be assembled by any means known to the person skilled in the art, for example with the aid of bonding enabling the stability of the heat exchanger (5) in terms of sealing and of pressure.

In one embodiment, with reference to FIG. 1b a layer of an electrically insulating material (4) which also ensures a sealing function is placed between the photovoltaic module and the heat exchanger (5). This material layer (4) may for example be a film of polyvinyl fluorine, and makes it possible to prevent rain or humidity from the ambient air from coming into direct contact with the photovoltaic module, thus avoiding any electrical problems, for example faulty contacts or short-circuits.

In one embodiment, with reference to FIG. 2, it is possible to omit the impermeable and electrically insulating material layer (4). In this case the sealing function is performed by the heat exchanger (5) which covers the entire surface of the photovoltaic module. The function of electrical insulation can be carried out for example by modifying the composition of the encapsulation (24), for example using a siliconised base, or for example by adding an insulating film on the face of the heat exchanger (5) in contact with the face of the photovoltaic module opposite the face exposed to the radiation.

The invention described in this document may be carried out according to a method of manufacture which now be described in detail.

In one embodiment, with reference to FIG. 1a, the photovoltaic module is obtained by encapsulation of the plurality of photovoltaic elements (3), according to a process of lamination described in the prior art documents and well known to the person skilled in the art. The process remains of the same type when a film of transparent material (1) is used on the face of the photovoltaic module exposed to the radiation, instead of a glass sheet.

In one embodiment, with reference to FIGS. 1b and 2 the photovoltaic module and the heat exchanger (5) are assembled following a second step of lamination. The transparent film (1) situated on the face of the photovoltaic module exposed to the radiation makes it possible to achieve flat laminations, without bonding defects, for example and in a non-limiting manner by avoiding the presence of air bubbles between the two materials.

In one embodiment, and preferably, the hybrid solar module is manufactured in the course of the same lamination operation. In this case, the lamination operation enables the assembly of the plurality of photovoltaic elements (3) in a encapsulation (21, 22), the deposition of the film (1) on the face of the photovoltaic module exposed to the radiation, the assembly of the photovoltaic module and of the heat exchanger (5), wherein a layer of insulating material (4) can be slid between the face of the photovoltaic module opposite the face exposed to the radiation and the heat exchanger (5), the whole assembly being held with the encapsulation (23, 24) which will be electrically neutral in the absence of said insulating layer (4).

Preferably, this lamination operation is effected according to a precise order. In order to avoid the presence of air bubbles between the layers of material, it is easier to deposit the less rigid layers on the more rigid ones. Thus the heat exchanger (5) which is most rigid corresponds to the first layer deposited, followed by the layer of encapsulation (23, 24), optionally the insulating layer (4) followed by a layer of encapsulation (22) as a function of the embodiment, then come the photovoltaic elements (3), the encapsulation (21) and finally the transparent material layer (1).

In one embodiment, the method of manufacture of the hybrid solar module is carried out with a heat exchanger (5) composed of two sub-parts (51, 52). The method is the same as the method described previously, that is to say the assembly of the plurality of photovoltaic elements (3) in a encapsulation (21, 22), the deposition of the film (1) on the face of the photovoltaic module exposed to the radiation, the assembly of the photovoltaic module and the first sub-part (51) of the heat exchanger (5), wherein a layer of insulating material (4) can be slid between the face of the photovoltaic module opposite the face exposed to the radiation and the heat exchanger (5), the whole assembly being held with the encapsulation (23, 24) which will be electrically neutral in the absence of said insulating layer (4). The two sub-parts (51, 52) of the heat exchanger (5) can be assembled by any means known to the person skilled in the art, for example with the aid of bonding enabling the stability of the heat exchanger (5) in terms of sealing and of pressure. Such a method has numerous advantages, in particular a greater freedom of choice in the shape of the heat exchanger (5), and a lamination operation facilitated by the absence of specific roughness on the surface of the heat exchanger (5).

The present application describes various technical characteristics and advantages with reference to the drawings and/or to various embodiments. The person skilled in the art will understand that the technical characteristics of a given embodiment may in fact be combined with characteristics of another embodiment unless explicitly mentioned otherwise or unless it is obvious that these characteristics are incompatible. In addition, the technical characteristics described in a given embodiment can be isolated from other characteristics of this embodiment unless explicitly mentioned otherwise.

It should be obvious to persons skilled in the art that the present invention allows embodiments in numerous other specific forms without departing from the scope of the invention as claimed. Consequently, the present embodiments should be considered by way of illustration, but may be modified within the field defined by the scope of the appended claims, and the invention should not be limited to the details given above.

1. A hybrid solar module installation, comprising at least one photovoltaic module comprising at least one semiconductor element (3) converting part of solar energy into electrical energy, one of the two faces of said module being exposed to radiation, at least one heat exchanger (5) placed facing the face of the photovoltaic module opposed to the face exposed to the radiation, in which a cooling fluid circulates which makes it possible to recover the heat energy accumulated or dissipated, of which the face in contact with the photovoltaic solar module is rigid and flat, the hybrid solar module installation comprising:
i. a layer (1) of transparent material suitable to be subjected to mechanical deformations compatible with the deformations undergone by the materials constituting the heat exchanger (5) and deposited on the face of the photovoltaic module receiving the radiation, said layer (1) being connected to the photovoltaic module by a first layer of encapsulating material (21); and
ii. a second layer of encapsulating material (23) deposited on the face of the photovoltaic module opposed to the face receiving the radiation in order to fix the heat exchanger (5) on this face opposing face of the photovoltaic module.

2. The installation as claimed in claim 1, wherein the hybrid solar module is compatible with the photovoltaic technologies based on semiconductors or existing organic technologies.

3. The installation as claimed in claim 1, wherein the layer (1) of transparent material covering the face of the photovoltaic module which is exposed to the radiation is based on fluoropolymer, said layer (1) of material being compatible with the lamination process.

4. The installation as claimed in claim 1, wherein the light transmission of the material layer (1) covering the face of the photovoltaic module subjected to the radiation is greater than the light transmission of glass.

5. The installation as claimed in claim 1, wherein the heat exchanger (5) is metal or made of a composite material.

6. The installation as claimed in claim 1, wherein the cooling of the photovoltaic module is ensured by the circulation of a liquid film in the heat exchanger (5).

7. The installation as claimed in claim 1, wherein the heat exchanger (5) comprises a first flat sub-part (51) in contact with the photovoltaic module, and a second sub-part (52) co-operating with the first sub-part (51) in order to form the circulation channels for the cooling fluid.

8. The installation as claimed in claim 1, wherein the composition of the encapsulation (24) joining the photovoltaic module to the heat exchanger (5) is modified in order also to make it an electrical insulation.

9. A method for manufacturing a hybrid solar module, comprising at least one photovoltaic module comprising at least one semiconductor element (3) converting part of solar energy into electrical energy, one of the two faces of said module being subjected to solar radiation, at least one heat exchanger (5) placed facing the face of the photovoltaic module opposed to the face exposed to the solar radiation, in which a cooling fluid circulates which makes it possible recover the heat energy accumulated or dissipated, the method comprises:
i. a step of depositing a layer of encapsulation (23, 34) on the face of at least a part of the heat exchanger (5) facing the face of the photovoltaic module opposite the face which is subjected to the radiation;
ii a step of positioning photovoltaic elements (3) on the layer of encapsulation (23, 24);
iii a step of depositing a layer of encapsulation (21) on the face of the photovoltaic module which is subjected to the radiation;
iv a step of positioning a transparent material layer (1) facing the face of the photovoltaic module which is subjected to the radiation; and
v a step of lamination of the hybrid solar module.

10. The method as claimed in claim 9, wherein before the positioning of the photovoltaic elements (3) in the step i a layer of insulating material (4) is inserted followed by the deposition of a layer of encapsulation (22) facing the face of the photovoltaic module opposite the face which is subjected to the radiation.

11. The method as claimed in claim 9, wherein the encapsulation of the photovoltaic module and the assembly of said module with the heat exchanger (5) may be carried out during the same step of lamination.

12. The method as claimed in claim 9, wherein a second sub-part (52) of the heat exchanger (5) is assembled with the part (51) assembled to the photovoltaic module, following the operation of lamination enabling assembly of the hybrid solar module.

13. The method as claimed in claim 9, wherein the step of depositing the layer of encapsulation on the face of the photovoltaic module which is subjected to the radiation is performed prior to the step of positioning the transparent material layer facing the face of the photovoltaic module which is subjected to the radiation.

14. The method as claimed in claim 9, wherein the step of positioning the transparent material layer facing the face of the photovoltaic module which is subjected to the radiation is performed prior to the step of depositing the layer of encapsulation on the face of at least a part of the heat exchanger facing the face of the photovoltaic module opposite the face which is subjected to the radiation.

15. The method as claimed in claim 9, wherein step iii is performed prior to step iv, step iv is performed prior to step i, step i is performed prior to step ii, and step ii is performed prior to step v.
